(19) United States
(12) Patent Application Publication
(10) Pub. No.: US 2025/0194138 A1
(43) Pub. Date: Jun. 12, 2025

(54) SEMICONDUCTOR STRUCTURE AND PREPARATION METHOD THEREOF

(71) Applicant: Enkris Semiconductor, Inc., Suzhou (CN)

(72) Inventor: Kai CHENG, Suzhou (CN)

(21) Appl. No.: 18/741,411

(22) Filed: Jun. 12, 2024

(30) Foreign Application Priority Data
Dec. 8, 2023 (CN) 202311685452.3

(51) Int. Cl. H01L 29/778; H01L 29/20; H01L 29/66

(52) U.S. Cl. CPC H10D 30/475; H10D 30/015; H10D 62/8503

(57) ABSTRACT

Provided are a semiconductor structure and a preparation method thereof. The semiconductor structure includes a substrate, a buffer layer, a channel layer, and a barrier layer that are sequentially stacked. The buffer layer includes carbon element doping. The buffer layer includes a first portion and a second portion that are distributed in a stack. The first portion is disposed on a side of the buffer layer adjacent to the substrate. In the direction of the substrate pointing to the channel layer, the carbon concentration in the first portion gradually increases with a preset trend, and the carbon concentration in the second portion gradually decreases. The buffer layer also includes a first insertion layer disposed between the first portion and the second portion. The first insertion layer includes an Al composition.

This application claims priority to Chinese Patent Application No. 2023116854523 filed Dec. 8, 2023, the disclosure of which is incorporated herein by reference in its entirety.

### TECHNICAL FIELD

The present disclosure relates to the technical field of power devices, in particular, a semiconductor structure and a preparation method thereof.

### BACKGROUND

A high electron mobility transistor (HEMT) is a heterojunction field effect transistor. An AlGaN/GaN HEMT structure is used as an example. The band gap of the AlGaN is greater than that of the GaN. When a heterojunction is formed, two-dimensional electron gas (2DEG) is formed at an interface between the AlGaN and the GaN. Therefore, the HEMT is also referred to as a 2DEG field effect transistor.

For a GaN-type HEMT, doping carbon impurities to a region located in a lower portion of 2DEG can improve the pinch-off characteristics or increase the cut-off voltage. However, electrons captured by charge traps composed of impurities hinder the formation of 2DEG and are particularly prone to current collapse. Although reducing the impurity doping concentration is beneficial to suppressing current collapse, inaccurate control of the thickness of a buffer layer makes it impossible to eliminate current collapse.

### SUMMARY

The present disclosure provides a semiconductor structure and a preparation method thereof, which can increase the breakdown voltage of a device without affecting the dynamic characteristics of the device, avoid current collapse, and prevent device leakage.

According to an aspect of the present disclosure, a semiconductor structure is provided.

The semiconductor structure includes a substrate, a buffer layer, a channel layer, and a barrier layer that are sequentially stacked.

The buffer layer includes carbon element doping. The buffer layer includes a first portion and a second portion that are distributed in a stack. The first portion is disposed on a side of the buffer layer adjacent to the substrate. In the direction of the substrate pointing to the channel layer, the carbon concentration in the first portion gradually increases with a preset trend, and the carbon concentration in the second portion gradually decreases.

The buffer layer also includes a first insertion layer disposed between the first portion and the second portion. The first insertion layer includes an Al composition.

The band gap of the first insertion layer is greater than the band gap of the first portion and the band gap of the second portion.

The first insertion layer is a III-nitride material, and the first insertion layer is a single-layer structure insertion layer or a superlattice insertion layer.

The first insertion layer includes the Al composition, and in the direction of the substrate pointing to the channel layer, the Al composition in the first insertion layer gradually increases, gradually decreases, or increases first and then decreases; and/or the carbon concentration in the second portion gradually decreasing includes that the carbon concentration in the second portion decreases linearly or periodically.

The carbon concentration in the first portion gradually increasing with the preset trend includes that the carbon concentration in the first portion increases linearly or periodically.

The buffer layer also includes at least one second insertion layer, and a second insertion layer includes an Al composition.

The first portion includes several first buffer sub-layers, and the at least one second insertion layer is disposed between two adjacent first buffer sub-layers in the several first buffer sub-layers.

And/or, the second portion includes several second buffer sub-layers, and the at least one second insertion layer is disposed between two adjacent second buffer sub-layers in the several second buffer sub-layers.

The carbon concentrations in the several first buffer sub-layers increase in a stepwise manner, and the carbon concentrations in the first buffer sub-layers disposed on two adjacent sides of the second insertion layer are different.

And/or, the carbon concentrations in the several second buffer sub-layers decrease in a stepwise manner, and the carbon concentrations in the first buffer sub-layers on two adjacent sides of the second insertion layer are different.

The carbon concentrations in the several first buffer sub-layers increase in a zigzag manner, and the carbon concentration change trends in the first buffer sub-layers disposed on two adjacent sides of the second insertion layer are different.

And/or, the carbon concentrations in the several second buffer sub-layers decrease in a zigzag manner, and the carbon concentration change trends in the first buffer sub-layers on two adjacent sides of the second insertion layer are different.

The semiconductor structure also includes a composition suppression layer.

The composition suppression layer is disposed between the buffer layer and the channel layer.

According to another aspect of the present disclosure, a method for preparing a semiconductor structure is provided. The method includes the following:

A substrate is provided, and a buffer layer, a channel layer, and a barrier layer are sequentially prepared on a side of the substrate.

Preparing the buffer layer includes doping the buffer layer with carbon elements. Preparing the buffer layer includes preparing a first portion, a first insertion layer, and a second portion that are distributed in a stack. The first portion is disposed on a side of the buffer layer adjacent to the substrate. In the direction of the substrate pointing to the channel layer, the carbon concentration in the first portion gradually increases with a preset trend, and the carbon concentration in the second portion gradually decreases. The first insertion layer includes an Al composition.

The carbon concentration in the first portion gradually increasing with the preset trend includes that the carbon concentration in the first portion increases linearly or periodically; and/or the carbon concentration in the second portion gradually decreasing includes that the carbon concentration in the second portion decreases linearly or periodically.

Preparing the buffer layer on the side of the substrate includes the following:

A first portion is prepared on a side of the substrate.

A first insertion layer is prepared on a side of the first portion away from the substrate.

A second portion is prepared on a side of the first insertion layer away from the first portion.

The first insertion layer includes the Al composition, and in the direction of the substrate pointing to the channel layer, the Al composition in the first insertion layer gradually increases, gradually decreases, or increases first and then decreases.

Preparing the buffer layer also includes preparing at least one second insertion layer, and a second insertion layer includes an Al composition.

Preparing the first portion includes preparing several first buffer sub-layers and preparing the second insertion layer between two adjacent first buffer sub-layers in the several first buffer sub-layers.

And/or, preparing the second portion includes preparing several second buffer sub-layers and preparing the second insertion layer between two adjacent second buffer sub-layers in the several second buffer sub-layers.

The carbon concentrations in the several first buffer sub-layers increase in a stepwise manner, and the carbon concentrations in the first buffer sub-layers disposed on two adjacent sides of the second insertion layer are different.

And/or, the carbon concentrations in the several second buffer sub-layers decrease in a stepwise manner, and the carbon concentrations in the first buffer sub-layers on two adjacent sides of the second insertion layer are different.

The carbon concentrations in the several first buffer sub-layers increase in a zigzag manner, and the carbon concentration change trends in the first buffer sub-layers disposed on two adjacent sides of the second insertion layer are different.

And/or, the carbon concentrations in the several second buffer sub-layers decrease in a zigzag manner, and the carbon concentration change trends in the first buffer sub-layers on two adjacent sides of the second insertion layer are different.

After preparing the buffer layer on the side of the substrate, the method also includes the following:

A composition suppression layer is prepared on a side of the buffer layer away from the substrate.

Preparing the buffer layer on the side of the substrate includes preparing multiple stacked structures formed by a combination of the first portion, the first insertion layer, and the second portion in sequence, and the multiple stacked structures are sequentially formed on the substrate.

The semiconductor structure provided by the technical solution of embodiments of the present disclosure includes a substrate, a buffer layer, a channel layer, and a barrier layer that are sequentially stacked; the buffer layer includes carbon element doping; the buffer layer includes a first portion and a second portion that are distributed in a stack; the first portion is disposed on a side of the buffer layer adjacent to the substrate; in the direction of the substrate pointing to the channel layer, the carbon concentration in the first portion gradually increases with a preset trend, and the carbon concentration in the second portion gradually decreases. In the embodiments of the present disclosure, the carbon concentration in the first portion of the buffer layer gradually increases with a preset trend, and the carbon concentration in the second portion gradually decreases; the buffer layer also includes a first insertion layer disposed between the first portion and the second portion; the first insertion layer includes an Al composition. The higher the carbon concentration is, the higher the breakdown voltage of a device is, which can better improve the performance of the device and prevent device leakage. The second portion adjacent to the channel layer is configured to gradually reduce the carbon concentration so that the breakdown voltage of the device can be increased, carbon compositions are prevented from being doped into the channel layer, the dynamic characteristics of the device are not affected, and current collapse is avoided. The configuration of the first insertion layer causes the energy band to mutate, and a polarization effect is produced. Thus, a quasi-triangular potential well is formed at the interface so that a large number of electrons are confined in the triangular well, which can further prevent device leakage.

It is to be understood that the contents described in this part are not intended to identify key or important features of embodiments of the present disclosure and are not intended to limit the scope of the present disclosure. Other features of the present disclosure are apparent from the description provided hereinafter.

### BRIEF DESCRIPTION OF DRAWINGS

To illustrate technical solutions in embodiments of the present disclosure more clearly, accompanying drawings used in the description of the embodiments are briefly described below. Apparently, the accompanying drawings described below illustrate part of embodiments of the present disclosure, and those of ordinary skill in the art may acquire other accompanying drawings based on the accompanying drawings described below on the premise that no creative work is done.

FIG. 1 is a diagram illustrating the structure of a semiconductor according to embodiment one of the present disclosure.

FIG. 2 is a diagram illustrating the carbon concentration change trend of a buffer layer according to embodiment one of the present disclosure.

FIG. 3 is a diagram illustrating the carbon concentration change trend of another buffer layer according to embodiment one of the present disclosure.

FIG. 4 is a diagram illustrating the carbon concentration change trend of another buffer layer according to embodiment one of the present disclosure.

FIG. 5 is a diagram illustrating the carbon concentration change trend of another buffer layer according to embodiment one of the present disclosure.

FIG. 6 is a diagram illustrating the structure of a semiconductor according to embodiment two of the present disclosure.

FIG. 7 is a diagram illustrating the structure of a semiconductor according to embodiment three of the present disclosure.

FIG. 8 is a diagram illustrating the structure of another semiconductor according to embodiment four of the present disclosure.

FIG. 9 is a diagram illustrating the structure of a semiconductor according to embodiment five of the present disclosure.

FIG. 10 is a flowchart for preparing a buffer layer according to embodiment six of the present disclosure.

### DETAILED DESCRIPTION

The solutions in embodiments of the present disclosure are described clearly and completely in conjunction with drawings in the embodiments of the present disclosure from which the solutions are better understood by those skilled in the art. Apparently, the embodiments described below are part, not all, of the embodiments of the present disclosure. Based on the embodiments described herein, all other embodiments acquired by those skilled in the art on the premise that no creative work is done are within the scope of the present disclosure.

It should be noted that the terms such as “first” and “second” described herein are used to distinguish between similar objects and are not necessarily used to describe a particular order or sequence. It should be understood that the data used in this manner are interchangeable where appropriate so that the embodiments of the present disclosure described herein may also be implemented in a sequence not illustrated or described herein. Additionally, terms “comprising”, “including”, and any other variations thereof are intended to encompass a non-exclusive inclusion. For example, a process, method, system, product, or device that includes a series of steps or units not only includes the expressly listed steps or units but may also include other steps or units that are not expressly listed or are inherent to such a process, method, product, or device.

### Embodiment One

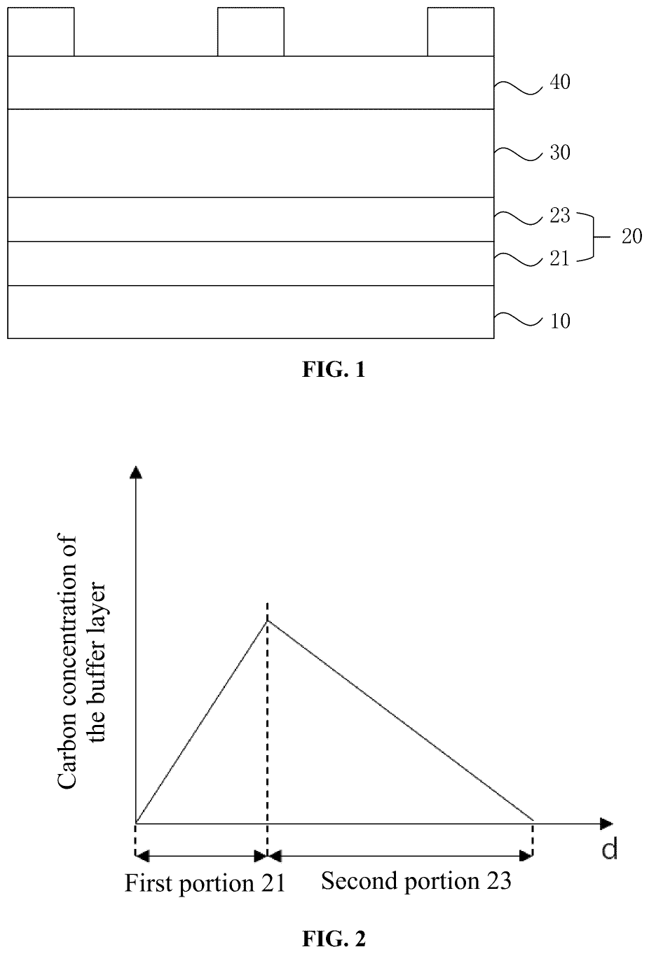

This embodiment of the present disclosure provides a semiconductor structure. FIG. 1 is a diagram illustrating the structure of a semiconductor according to embodiment one of the present disclosure. FIG. 2 is a diagram illustrating the carbon concentration change trend of a buffer layer according to embodiment one of the present disclosure. With reference to FIG. 1 and FIG. 2, the semiconductor structure includes a substrate 10, a buffer layer 20, a channel layer 30, and a barrier layer 40 that are sequentially stacked; the buffer layer 20 includes carbon element doping; the buffer layer 20 includes a first portion 21 and a second portion 23 that are distributed in a stack; the first portion 21 is disposed on a side of the buffer layer 20 adjacent to the substrate 10; in the direction of the substrate 10 pointing to the channel layer 30, the carbon concentration in the first portion 21 gradually increases with a preset trend, and the carbon concentration in the second portion 23 gradually decreases.

The semiconductor structure may be a gallium nitride-based power device. Illustratively, the semiconductor structure may be a high-electron-mobility transistor (HEMT). The device structure also includes a gate disposed on a side of the barrier layer 40 away from the substrate 10 and a drain and a source disposed on two sides of the gate.

The buffer layer 20 includes carbon element doping, which can increase the resistance value of the buffer layer 20, thereby reducing the leakage of the buffer layer 20 and increasing the breakdown voltage of the device. The carbon concentration in the first portion 21 of the buffer layer 20 gradually increases with a preset trend. The higher the carbon concentration is, the higher the resistance of the buffer layer 20 is, and the higher the breakdown voltage of the device is, which can better improve the performance of the device. The carbon concentration in the second portion 23 gradually decreases because if the carbon concentration in the second portion 23 is excessively high, the two-dimensional electron gas concentration in the channel layer 30 decreases, thereby affecting the dynamic characteristics of the device. Therefore, it is necessary to configure the first portion 21 of the buffer layer 20 adjacent to the substrate 10 such that the carbon concentration gradually increases with a preset trend, and it is necessary to configure the second portion 23 of the buffer layer 20 adjacent to the channel layer 30 such that the carbon concentration gradually decreases. In this manner, the breakdown voltage of the device can be increased without affecting the dynamic characteristics of the device, current collapse is avoided, and device leakage is prevented.

The semiconductor structure provided by the technical solution of this embodiment of the present disclosure includes a substrate 10, a buffer layer 20, a channel layer 30, and a barrier layer 40 that are sequentially stacked; the buffer layer 20 includes carbon element doping; the buffer layer 20 includes a first portion 21 and a second portion 23 that are distributed in a stack; the first portion 21 is disposed on a side of the buffer layer 20 adjacent to the substrate 10; in the direction of the substrate 10 pointing to the channel layer 30, the carbon concentration in the first portion 21 gradually increases with a preset trend, and the carbon concentration in the second portion 23 gradually decreases. In this embodiment of the present disclosure, the carbon concentration in the first portion 21 of the buffer layer 20 gradually increases with a preset trend, and the carbon concentration in the second portion 23 gradually decreases. The higher the carbon concentration is, the higher the breakdown voltage of the device is, which can better improve the performance of the device and prevent device leakage. The second portion 23 adjacent to the channel layer 30 is configured to gradually reduce the carbon concentration so that the breakdown voltage of the device can be increased, carbon compositions are prevented from being doped into the channel layer, and the dynamic characteristics of the device are not affected.

With reference to FIG. 1, the carbon concentration in the first portion 21 gradually increasing with the preset trend includes that the carbon concentration in the first portion 21 increases linearly or periodically. In other embodiments, the carbon concentration in the second portion 23 gradually decreasing includes that the carbon concentration in the second portion 23 decreases linearly or periodically.

With reference to FIG. 2, the horizontal axis direction is the thickness direction of the buffer layer 20, the abscissa d denotes the thickness distance between the buffer layer 20 and the substrate 10, the ordinate is the carbon concentration of the buffer layer, and the start point is the carbon concentration in the buffer layer 20 adjacent to the substrate 10; the carbon concentration in the first portion 21 increases linearly and gradually increases, and the carbon concentration in the second portion 23 decreases linearly and gradually decreases.

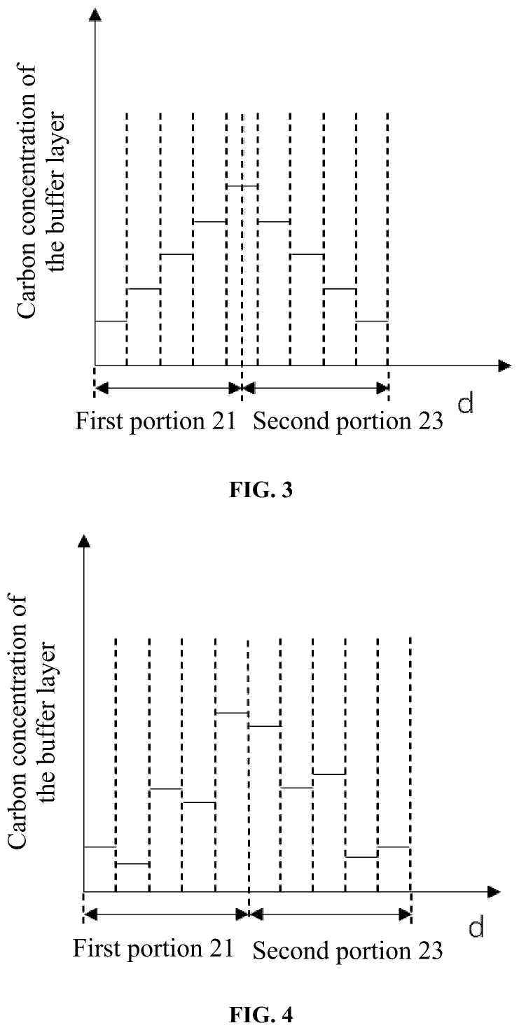

FIG. 3 is a diagram illustrating the carbon concentration change trend of another buffer layer according to embodiment one of the present disclosure. With reference to FIG. 3, the horizontal axis direction is the thickness direction of the buffer layer 20, the abscissa d denotes the thickness distance between the buffer layer 20 and the substrate 10, and the ordinate is the carbon concentration of the buffer layer. That is, in the direction of the substrate 10 pointing to the channel layer 30, the carbon concentration in the first portion 21 increases periodically, the periodic increase may be a stepwise increase, and the carbon concentration in the first portion 21 adjacent to the substrate 10 is less than the carbon concentration in the first portion 21 away from the substrate 10. In other embodiments, in the direction of the substrate 10 pointing to the channel layer 30, the carbon concentration in the second portion 23 decreases periodically, the periodic decrease may be a stepwise decrease, and the carbon concentration in the second portion 23 adjacent to the substrate 10 is greater than the carbon concentration in the second portion 23 away from the substrate 10.

FIG. 4 is a diagram illustrating the carbon concentration change trend of another buffer layer according to embodiment one of the present disclosure. With reference to FIG. 4, the horizontal axis direction is the thickness direction of the buffer layer 20, the abscissa d denotes the thickness distance between the buffer layer 20 and the substrate 10, and the ordinate is the carbon concentration of the buffer layer; the carbon concentration in the first portion 21 increases periodically, and the carbon concentration in the first portion 21 increases stepwise in each cycle. In each cycle, the carbon concentration in the first portion 21 adjacent to the substrate 10 is less than the carbon concentration in the first portion 21 away from the substrate 10. In adjacent cycles, the maximum value of the carbon concentration in the first portion 21 of the next cycle is greater than the maximum value of the carbon concentration in the first portion 21 of the previous cycle, and the minimum value of the carbon concentration in the first portion 21 of the next cycle is less than the maximum value of the carbon concentration in the first portion 21 of the previous cycle. That is, the carbon concentration in the first portion 21 increases in an oscillatory manner. In other embodiments, in the direction of the substrate 10 pointing to the channel layer 30, the carbon concentration in the second portion 23 decreases periodically, and carbon concentration in the second portion 23 decreases stepwise in each cycle. In each cycle, the carbon concentration in the second portion 23 adjacent to the substrate 10 is greater than the carbon concentration in the second portion 23 away from the substrate 10. In adjacent cycles, the minimum value of the carbon concentration in the second portion 23 of the next cycle is less than the minimum value of the carbon concentration in the second portion 23 of the previous cycle, and the maximum value of the carbon concentration in the second portion 23 of the next cycle is greater than the minimum value of the carbon concentration in the second portion 23 of the previous cycle. That is, the carbon concentration in the second portion 23 decreases in an oscillatory manner.

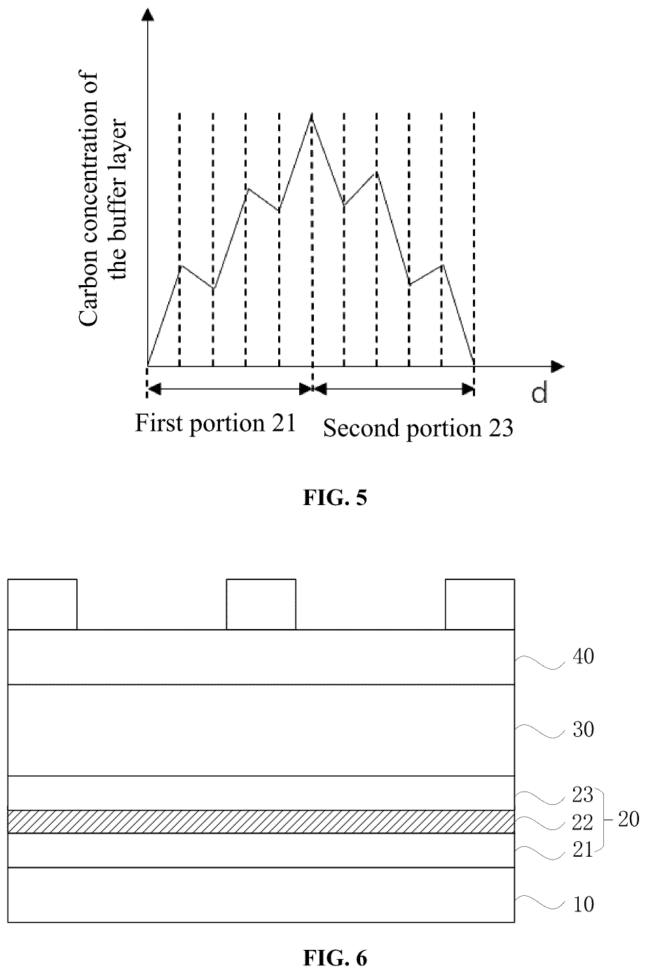

FIG. 5 is a diagram illustrating the carbon concentration change trend of another buffer layer according to embodiment one of the present disclosure. With reference to FIG. 5, the horizontal axis direction is the thickness direction of the buffer layer 20, the abscissa d denotes the thickness distance between the buffer layer 20 and the substrate 10, and the ordinate is the carbon concentration of the buffer layer; the carbon concentration in the first portion 21 increases periodically, and the periodic increase may be a zigzag-like increase; the carbon concentration in the first portion 21 in each zigzag cycle gradually increases and then gradually decreases to increase the device breakdown voltage and further prevent leakage. In other embodiments, the carbon concentration of the second portion 23 decreases periodically, and the periodic decrease may be a zigzag-like decrease; the carbon concentration in the second portion 23 in each zigzag cycle gradually decreases and then gradually increases to increase the device breakdown voltage and further prevent leakage.

### Embodiment Two

The present disclosure provides a semiconductor structure based on the preceding embodiment. The only difference is as follows: With reference to FIG. 6, FIG. 6 is a diagram illustrating the structure of a semiconductor according to embodiment two of the present disclosure; the buffer layer 20 also includes a first insertion layer 22 disposed between the first portion 21 and the second portion 23.

The first insertion layer 22 may be configured to prevent device leakage. The material of the first insertion layer 22 is a III-nitride material. For example, the material may be any one of AlGaN, AlN/GaN, or AlGaN/GaN.

With reference to FIG. 6, the band gap of the first insertion layer 22 is greater than the band gap of the first portion 21 and the band gap of the second portion 23.

The band gap of the first insertion layer 22 is greater than the band gap of the first portion 21 and the band gap of the second portion 23. Since the band gap of the first insertion layer 22 is different from the band gap of the first portion 21 and the band gap of the second portion 23, the energy band mutates, and the resulting polarization effect causes a quasi-triangular potential well to be formed at the interface so that a large number of electrons are confined in the triangular well. These electrons are quantized in the direction perpendicular to the heterojunction interface and can inhibit the movement of electrons in the direction perpendicular to the heterojunction interface to further prevent the buffer layer 20 from leaking downward. In this manner, the resistivity is increased, and the two-dimensional electron gas concentration in the channel layer 30 is ensured.

With reference to FIG. 6, the first insertion layer 22 is a III-nitride material, and the first insertion layer 22 is a single-layer structure insertion layer or a superlattice insertion layer.

The single-layer structure insertion layer may be an AlGaN insertion layer. The superlattice insertion layer may be one of an AlN/GaN superlattice insertion layer or an AlGaN/GaN superlattice insertion layer.

With reference to FIG. 6, the first insertion layer 22 includes the Al composition, and in the direction of the substrate 10 pointing to the channel layer 30, the Al composition in the first insertion layer 22 gradually increases, gradually decreases, or increases first and then decreases.

The Al composition in the first insertion layer 22 gradually increases, gradually decreases, or first increases and then decreases so that the energy band of the first insertion layer 22 changes, which can further suppress the movement of electrons. The electrons move along the bottom of the conduction band. Compared with a flat energy band, a changing energy band is more likely to block electrons and further prevent leakage.

### Embodiment Three

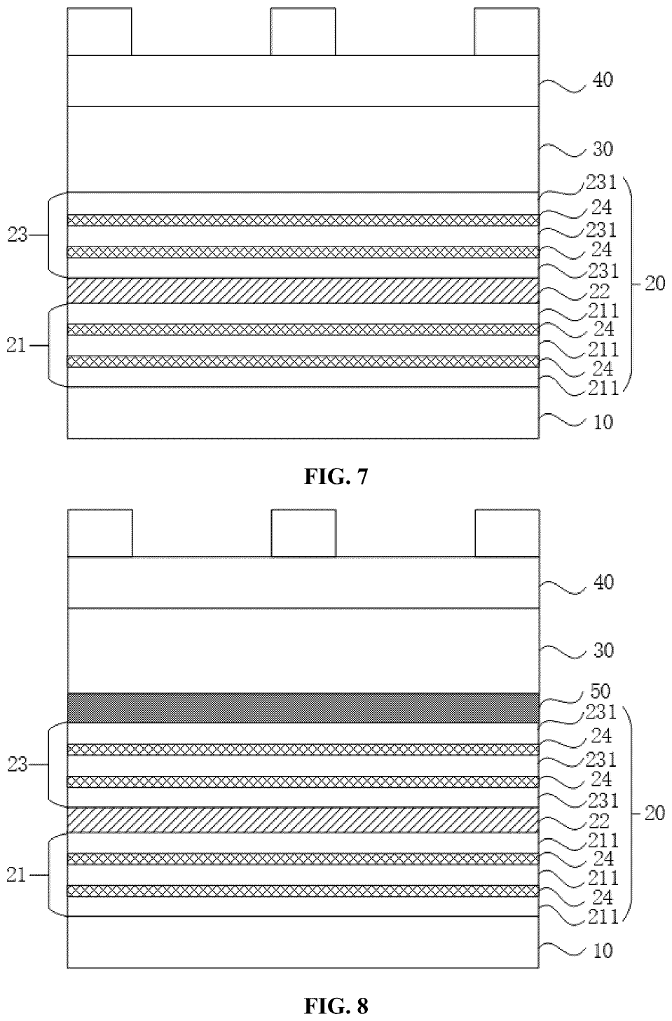

The semiconductor structure provided by embodiment three of the present disclosure is substantially the same as that of embodiment one and embodiment two. The only difference is as follows: With reference to FIG. 7, FIG. 7 is a diagram illustrating the structure of another semiconductor according to embodiment three of the present disclosure; the buffer layer 20 also includes at least one second insertion layer 24, and the second insertion layer 24 includes an Al composition; the first portion 21 includes several first buffer sub-layers 211, and at least one second insertion layer 24 is disposed between two adjacent first buffer sub-layers 211 in the several first buffer sub-layers 211; and/or, the second portion 23 includes several second buffer sub-layers 231, and at least one second insertion layer 24 is disposed between two adjacent second buffer sub-layers 231 in the several second buffer sub-layers 231.

The second insertion layer 24 has the same beneficial effect as the first insertion layer 22. The second insertion layer 24 may also be configured to further prevent device leakage. The material of the second insertion layer 24 is a III-nitride material. For example, the material may be any one of AlGaN, AlN/GaN, or AlGaN/GaN. At least one second insertion layer 24 is disposed between two adjacent first buffer sub-layers 211 in the several first buffer sub-layers 211. One second insertion layer 24 may be disposed between two adjacent first buffer sub-layers 211; alternatively, multiple second insertion layers 24 may be disposed between two adjacent first buffer sub-layers 211. The second insertion layer 24 may be disposed between any two adjacent first buffer sub-layers 211; alternatively, the second insertion layer 24 may be disposed between only part of adjacent first buffer sub-layers 211. The first insertion layer 22 includes the Al composition, and in the direction of the substrate 10 pointing to the channel layer 30, the Al composition in the first insertion layer 22 gradually increases, gradually decreases, or increases first and then decreases.

With reference to FIG. 7, the carbon concentrations in the several first buffer sub-layers 211 increase in a stepwise manner, and the carbon concentrations in the first buffer sub-layers 211 disposed on two adjacent sides of the second insertion layer 24 are different; and/or, the carbon concentrations in the several second buffer sub-layers 231 decrease in a stepwise manner, and the carbon concentrations in the second buffer sub-layers 231 on two adjacent sides of the second insertion layer 24 are different.

For a stepwise increase in the carbon concentrations, reference may be further made to FIG. 3 and FIG. 4. The carbon concentration in each first buffer sub-layer 211 increases in a stepwise manner, or after adjacent first buffer sub-layers 211 in first buffer sub-layers 211 are combined into a periodic structure, the carbon concentration in the first portion 21 increases periodically; and/or, the carbon concentration in each second buffer sub-layer 231 decreases a stepwise manner, or after adjacent second buffer sub-layers 231 in second buffer sub-layers 231 are combined into a periodic structure, the carbon concentration in the second portion 23 decreases periodically.

With reference to FIG. 7, the carbon concentrations in the several first buffer sub-layers 211 increase in a zigzag manner, and the carbon concentration change trends in the first buffer sub-layers 211 disposed on two adjacent sides of the second insertion layer 24 are different; and/or, the carbon concentrations in the several second buffer sub-layers 231 decrease in a zigzag manner, and the carbon concentration change trends in the second buffer sub-layers 231 on two adjacent sides of the second insertion layer 24 are different.

For a zigzag-like increase of the carbon concentrations, reference may be further made to FIG. 5. The carbon concentration change trends in the first buffer sub-layers 211 disposed on two adjacent sides of each second insertion layer 24 are different, the carbon concentration in the first buffer sub-layer 211 adjacent to the substrate 10 gradually increases, and the carbon concentration in the first buffer sub-layer 211 away from the substrate 10 gradually decreases; alternatively, the carbon concentration in the first buffer sub-layer 211 adjacent to the substrate 10 gradually decreases, and the carbon concentration in the first buffer sub-layer 211 away from the substrate 10 gradually increases. And/or, the carbon concentration change trends in the second buffer sub-layers disposed on two adjacent sides of each second insertion layer 24 are different, the carbon concentration in the second buffer sub-layer 231 adjacent to the substrate 10 gradually decreases, and the carbon concentration in the second buffer sub-layer 231 away from the substrate 10 gradually increases; alternatively, the carbon concentration in the second buffer sub-layer 231 adjacent to the substrate 10 gradually increases, and the carbon concentration in the second buffer sub-layer 231 away from the substrate 10 gradually decreases.

### Embodiment Four

The semiconductor structure provided by embodiment four of the present disclosure is substantially the same as that of embodiment one, embodiment two, and embodiment three. The only difference is as follows: FIG. 8 is a diagram illustrating the structure of another semiconductor according to embodiment four of the present disclosure. With reference to FIG. 8, the semiconductor structure also includes a composition suppression layer 50 disposed between the buffer layer 20 and the channel layer 30.

The band gap of the composition suppression layer 50 is greater than the band gap of buffer layer 20. The material of the composition suppression layer 50 may be an AlN material, which can inhibit carbon impurities from diffusing into the channel layer 30 and further avoid carbon impurity contamination in the channel.

### Embodiment Five

The content of embodiment five is substantially the same as that of any one of embodiments one to four. The only difference is as follows: As shown in FIG. 9, FIG. 9 is a diagram illustrating the structure of a semiconductor according to embodiment five; the buffer layer 20 includes multiple stacked structures formed by a combination of the first portion 21, the first insertion layer 22, and the second portion 23 in sequence, and the multiple stacked structures are sequentially formed on the substrate 10.

### Embodiment Six

Embodiment six of the present disclosure provides a method for preparing a semiconductor structure based on the preceding embodiments. With reference to FIG. 1, the preparation method includes providing a substrate 10 and sequentially preparing a buffer layer 20, a channel layer 30, and a barrier layer 40 on a side of the substrate 10.

Preparing the buffer layer 20 includes doping the buffer layer 20 with carbon elements. Preparing the buffer layer 20 includes preparing a first portion 21 and a second portion 23 that are sequentially stacked on the substrate 10. The first portion 21 is disposed on a side of the buffer layer 20 adjacent to the substrate 10. In the direction of the substrate 10 pointing to the channel layer 30, the carbon concentration in the first portion 21 gradually increases with a preset trend, and the carbon concentration in the second portion 23 gradually decreases.

With reference to FIG. 1, the carbon concentration in the first portion 21 gradually increasing with the preset trend includes that the carbon concentration in the first portion 21 increases linearly or periodically.

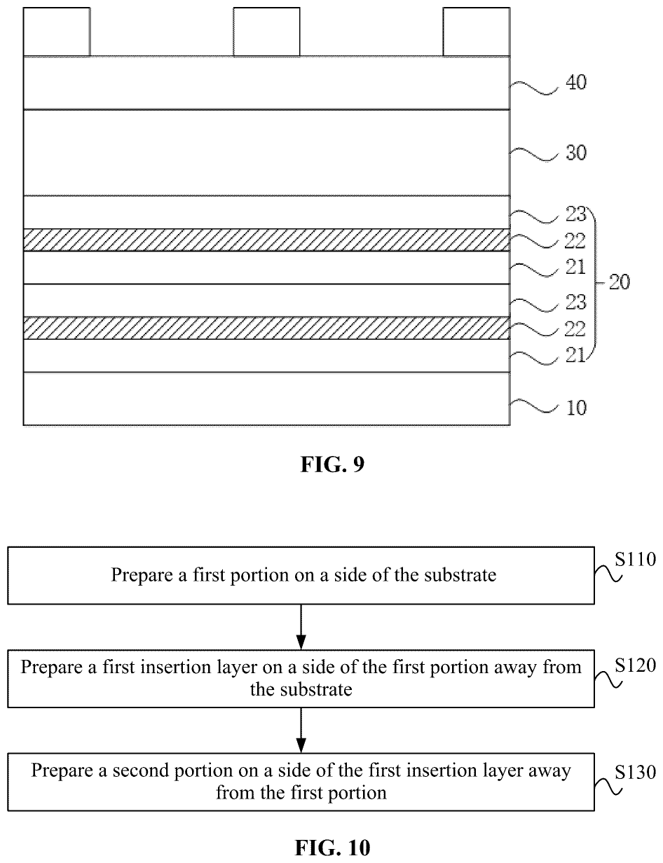

FIG. 10 is a flowchart for preparing a buffer layer according to embodiment six of the present disclosure. With reference to FIG. 6 and FIG. 10, preparing the buffer layer 20 on the side of the substrate 10 includes the steps below.

In S110, a first portion 21 is prepared on a side of the substrate 10.

In S120, a first insertion layer 22 is prepared on a side of the first portion 21 away from the substrate 10.

In S130, a second portion 23 is prepared on a side of the first insertion layer 22 away from the first portion 21.

With reference to FIG. 6, the first insertion layer 22 includes the Al composition, and in the direction of the substrate 10 pointing to the channel layer 30, the Al composition in the first insertion layer 22 gradually increases, gradually decreases, or increases first and then decreases.

With reference to FIG. 7, preparing the first portion 21 includes preparing several first buffer sub-layers 211; and/or, preparing the second portion 23 includes preparing several second buffer sub-layers 231. Preparing the buffer layer 20 on the side of the substrate 10 also includes the steps below.

The second insertion layer 24 is prepared between two adjacent first buffer sub-layers 211 in the several first buffer sub-layers 211. And/or, the second insertion layer 24 is prepared between two adjacent second buffer sub-layers 231 in the several second buffer sub-layers 231. The second insertion layer 24 includes the Al composition, and in the direction of the substrate 10 pointing to the channel layer 30, the Al composition in the second insertion layer 24 gradually increases, gradually decreases, or increases first and then decreases.

With reference to FIG. 7, the carbon concentrations in the several first buffer sub-layers 211 increase in a stepwise manner, and the carbon concentrations in the first buffer sub-layers 211 disposed on two adjacent sides of the second insertion layer 24 are different; and/or, the carbon concentrations in the several second buffer sub-layers 231 decrease in a stepwise manner, and the carbon concentrations in the second buffer sub-layers 231 on two adjacent sides of the second insertion layer 24 are different.

With reference to FIG. 7, the carbon concentrations in the several first buffer sub-layers 211 increase in a zigzag manner, and the carbon concentration change trends in the first buffer sub-layers 211 disposed on two adjacent sides of the second insertion layer 24 are different; and/or, the carbon concentrations in the several second buffer sub-layers 231 decrease in a zigzag manner, and the carbon concentration change trends in the second buffer sub-layers 231 on two adjacent sides of the second insertion layer 24 are different.

With reference to FIG. 9, preparing the buffer layer 20 on the side of the substrate 10 includes preparing multiple stacked structures formed by a combination of the first portion 21, the first insertion layer 22, and the second portion 23 in sequence, and the multiple stacked structures are sequentially formed on the substrate 10.

With reference to FIG. 8, after preparing the buffer layer 20 on the side of the substrate 10, the method also includes the step below.

A composition suppression layer 50 is prepared on a side of the buffer layer 20 away from the substrate 10.

The method for preparing a semiconductor structure according to embodiments of the present disclosure has the same beneficial effects as the semiconductor structure described in any embodiment of the present disclosure.

It is to be understood that various forms of processes shown above may be adopted with steps reordered, added, or deleted. For example, the steps described in the present disclosure may be performed in parallel, sequentially, or in different orders, as long as the desired results of the technical solutions of the present disclosure can be achieved, and no limitation is imposed herein.

The preceding embodiments do not limit the scope of the present disclosure. It is to be understood by those skilled in the art that various modifications, combinations, sub-combinations, and substitutions may be performed according to design requirements and other factors. Any modifications, equivalent substitutions, improvements, and the like made within the spirit and principle of the present disclosure are within the scope of the present disclosure.

What is claimed is:

1. A semiconductor structure, comprising:
a substrate, a buffer layer, a channel layer, and a barrier layer that are sequentially stacked;
wherein the buffer layer comprises carbon element doping, and the buffer layer comprises a first portion and a second portion that are distributed in a stack, and wherein the first portion is disposed on a side of the buffer layer adjacent to the substrate, and in a direction of the substrate pointing to the channel layer, a carbon concentration in the first portion gradually increases with a preset trend, and a carbon concentration in the second portion gradually decreases; and
wherein the buffer layer further comprises a first insertion layer disposed between the first portion and the second portion, and the first insertion layer comprises an Al composition.

2. The semiconductor structure of claim 1, wherein
a band gap of the first insertion layer is greater than a band gap of the first portion and a band gap of the second portion.

3. The semiconductor structure of claim 1, wherein
a material of the first insertion layer is III-nitride, and the first insertion layer is a single-layer structure insertion layer or a superlattice insertion layer.

4. The semiconductor structure of claim 1, wherein
the first insertion layer comprises the Al composition, and in the direction of the substrate pointing to the channel layer, the Al composition in the first insertion layer gradually increases, gradually decreases, or increases first and then decreases.

5. The semiconductor structure of claim 1, wherein
the carbon concentration in the first portion gradually increasing with the preset trend comprises that the carbon concentration in the first portion increases linearly or periodically;
and/or, the carbon concentration in the second portion gradually decreasing comprises that the carbon concentration in the second portion decreases linearly or periodically.

6. The semiconductor structure of claim 1, wherein
the buffer layer further comprises at least one second insertion layer, and a second insertion layer of the at least one second insertion layer comprises an Al composition; wherein
the first portion comprises a plurality of first buffer sub-layers, and the at least one second insertion layer is disposed between two adjacent first buffer sub-layers of the plurality of first buffer sub-layers;
and/or, the second portion comprises a plurality of second buffer sub-layers, and the at least one second insertion layer is disposed between two adjacent second buffer sub-layers of the plurality of second buffer sub-layers.

7. The semiconductor structure of claim 6, wherein
carbon concentrations in the plurality of first buffer sub-layers increase in a stepwise manner, and carbon concentrations in the first buffer sub-layers disposed on two adjacent sides of the second insertion layer are different;
and/or, carbon concentrations in the plurality of second buffer sub-layers decrease in a stepwise manner, and carbon concentrations in the first buffer sub-layers on two adjacent sides of the second insertion layer are different.

8. The semiconductor structure of claim 6, wherein
carbon concentrations in the plurality of first buffer sub-layers increase in a zigzag manner, and carbon concentration change trends in the first buffer sub-layers disposed on two adjacent sides of the second insertion layer are different;
and/or, carbon concentrations in the plurality of second buffer sub-layers decrease in a zigzag manner, and carbon concentration change trends in the first buffer sub-layers on two adjacent sides of the second insertion layer are different.

9. The semiconductor structure of claim 1, further comprising:
a composition suppression layer disposed between the buffer layer and the channel layer.

10. The semiconductor structure of claim 1, wherein
the buffer layer comprises a plurality of stacked structures each of which is formed by a combination of the first portion, the first insertion layer, and the second portion in sequence, and the plurality of stacked structures are sequentially formed on the substrate.

11. A method for preparing a semiconductor structure, comprising:
providing a substrate, and sequentially preparing a buffer layer, a channel layer, and a barrier layer on a side of the substrate;
wherein preparing the buffer layer comprises doping the buffer layer with carbon elements, and preparing the buffer layer comprises preparing a first portion, a first insertion layer, and a second portion that are distributed in a stack, wherein the first portion is disposed on a side of the buffer layer adjacent to the substrate, and in a direction of the substrate pointing to the channel layer, a carbon concentration in the first portion gradually increases with a preset trend, and a carbon concentration in the second portion gradually decreases; and the first insertion layer comprises an Al composition.

12. The method for preparing the semiconductor structure of claim 11, wherein
the carbon concentration in the first portion gradually increasing with the preset trend comprises that the carbon concentration in the first portion increases linearly or periodically;
and/or the carbon concentration in the second portion gradually decreasing comprises that the carbon concentration in the second portion decreases linearly or periodically.

13. The method for preparing the semiconductor structure of claim 11, wherein
the first insertion layer comprises the Al composition, and in the direction of the substrate pointing to the channel layer, the Al composition in the first insertion layer gradually increases, gradually decreases, or increases first and then decreases.

14. The method for preparing the semiconductor structure of claim 11, wherein preparing the buffer layer further comprises preparing at least one second insertion layer, and a second insertion layer of the at least one second insertion layer comprises an Al composition; wherein
preparing the first portion comprises preparing a plurality of first buffer sub-layers and preparing the second insertion layer between two adjacent first buffer sub-layers in the plurality of first buffer sub-layers;
and/or preparing the second portion comprises preparing a plurality of second buffer sub-layers and preparing the second insertion layer between two adjacent second buffer sub-layers of the plurality of second buffer sub-layers.

15. The method for preparing the semiconductor structure of claim 14, wherein
carbon concentrations in the plurality of first buffer sub-layers increase in a stepwise manner, and carbon concentrations in the first buffer sub-layers disposed on two adjacent sides of the second insertion layer are different;
and/or carbon concentrations in the plurality of second buffer sub-layers decrease in a stepwise manner, and carbon concentrations in the first buffer sub-layers on two adjacent sides of the second insertion layer are different.

16. The method for preparing the semiconductor structure of claim 14, wherein
carbon concentrations in the plurality of first buffer sub-layers increase in a zigzag manner, and carbon concentration change trends in the first buffer sub-layers disposed on two adjacent sides of the second insertion layer are different;
and/or carbon concentrations in the plurality of second buffer sub-layers decrease in a zigzag manner, and carbon concentration change trends in the first buffer sub-layers on two adjacent sides of the second insertion layer are different.

17. The method for preparing the semiconductor structure of claim 11, wherein after preparing the buffer layer on the side of the substrate, the method further comprises:
preparing a composition suppression layer on a side of the buffer layer away from the substrate.

18. The method for preparing the semiconductor structure of claim 11, wherein preparing the buffer layer on the side of the substrate comprises preparing a plurality of stacked structures each of which is formed by a combination of the first portion, the first insertion layer, and the second portion in sequence, and the plurality of stacked structures are sequentially formed on the substrate.
